(19) United States
(12) Patent Application Publication
(10) Pub. No.: US 2016/0342089 A1
(43) Pub. Date: Nov. 24, 2016

(54) METHOD FOR DIRECTED SELF-ASSEMBLY (DSA) OF A BLOCK COPOLYMER (BCP) USING A TOPOGRAPHIC PATTERN

(71) Applicant: HGST Netherlands B.V., Amsterdam (NL)

(72) Inventors: Ricardo Ruiz, Santa Clara, CA (US); Lei Wan, San Jose, CA (US)

(21) Appl. No.: 14/718,236

(22) Filed: May 21, 2015

(51) Int. Cl. G03F 7/16; B05D 1/38; B05D 3/10; B05D 1/32

(52) U.S. Cl. CPC G03F 7/165; B05D 1/32; B05D 1/38; B05D 3/107

(57) ABSTRACT

A method uses a topographic pattern for directed self-assembly (DSA) of block copolymers (BCPs). Conventional lithography generates a topographic pattern of guiding stripes that have sidewalls that preferentially wet one of the blocks. A BCP blend with functional homopolymers, called “inks”, is deposited and annealed on the topographic pattern. After annealing, the BCP blend is guided to self-assemble by the topographic pattern. The inks selectively distribute into blocks, and part of the inks graft in the trenches between the topographic features. The BCP blend layer is rinsed away, leaving the grafted inks that form a chemical pattern. A second layer of BCP is deposited on this chemical pattern and annealed, resulting in DSA of the second BCP. After removal of one of the BCP blocks of the second BCP, the remaining blocks can serve as an etch mask.

### BACKGROUND OF THE INVENTION

1. Field of the Invention

This invention relates generally to the directed self-assembly (DSA) of block copolymers (BCPs), and more particularly to the DSA of BCPs using a topographic pattern as a patterned sublayer.

2. Description of the Related Art

Block copolymer (BCP) patterns are useful and viable alternatives for patterning at dimensions not achievable by conventional lithographic processes. Thin films of block copolymers (BCPs) self-assemble at dimensions in the range of 5-50 nm, making them very attractive for lithographic applications. BCPs are polymeric chains with two or more incompatible blocks joined by covalent bonds. By annealing the polymer above its glass transition temperature (T_{g}) the polymer chains gain enough mobility to diffuse. The strength of the incompatibility between the blocks will drive the system towards an equilibrium morphology which results in periodic, uniform patterns with a periodicity or natural pitch (L₀) of the repeating structural units. Depending on the volume fraction of the blocks, one block copolymer may form sphere, cylinder or lamellae morphology. To control the orientation of the morphologies is one of the key factors for block copolymer lithography. Generally, cylinder or lamellae that are oriented perpendicularly to the substrate are preferred or required. Translational ordering and feature registration are required for some applications of block copolymer patterns. Directed self-assembly (DSA) of block copolymers (BCPs) has been proposed for generating patterns in semiconductor manufacturing, for example, for patterning parallel generally straight lines in MPU, DRAM and NAND flash devices, and more recently for patterning parallel line arrays for FinFET devices. DSA of BCPs can also be used for making imprint templates, which have application in making patterned-media magnetic recording disks and semiconductor devices.

DSA of BCPs by use of a patterned sublayer for the BCP film is well-known. After the BCP components self-assemble on the patterned sublayer, one of the components is selectively removed, leaving the other component with the desired pattern, which can be used as an etch mask to transfer the pattern into an underlying substrate. The etched substrate can be used as an imprint template.

Chemoepitaxy (the use of a chemical contrast pattern as the sublayer) and graphoepitaxy (the use of a topographic pattern as the sublayer) are the two techniques presently used with DSA to provide long-range ordered and registered BCP patterns. To obtain perfect DSA over the entire patterned area of the substrate using a chemical contrast pattern, the chemical guiding features need to have pitch less than about 5L₀ and a width of either ˜0.5L₀ or ˜1.5L₀, which is difficult to achieve. For a topographic pattern, wherein the guiding features are relatively tall features, the guiding features can be much wider and have a much larger pitch. While the critical dimensions of the topographic guiding features won't affect DSA in the trenches between the features, the tall guiding features will affect DSA and/or the following pattern transfer. Therefore, valuable area is lost due to the topographic features. Other known solutions may be restricted to the formation of stripes by cylindrical block copolymers or may have a very narrow or no process window to achieve defect-free patterns over the entire area.

What is needed is a method for DSA of BCPs using a topographic pattern that enables the BCPs to be patterned over the entire patterned area of the substrate with a robust process window and amenable to lamellae-forming block copolymers.

### SUMMARY OF THE INVENTION

Embodiments of the invention relate to a method to improve the process of DSA of BCPs on topographic prepatterns. In a first embodiment, a conventional lithography process is used to generate a patterned sublayer whose guiding features are substantially higher than the interspatial trenches. This topographic pattern can be generated by any conventional lithography process. Then a BCP blend with a small portion of functional homopolymers is deposited and annealed on the topographic pattern. A functional homopolymer, referred to as an ink, is typically the same as one of the BCP blocks. After annealing, the BCP blend will be guided by the topographic pattern. Because the height of the topographic features is higher than the BCP film thickness, graphoepitaxy DSA occurs. The inks will selectively distribute into blocks, and part of the inks will graft in the trenches between the topographic features. The BCP blend layer is then rinsed away, leaving the grafted inks The grafted inks will form a 1:1 chemical pattern with the same geometry as the BCP. The features of the topographic prepatterns can be removed in a solvent. The resulting guiding pattern is thus changed to a chemical pattern with 1:1 chemical pattern in the trenches. This new chemical pattern will be acceptable for a second DSA of a BCP layer on the entire patterned area with a thickness of typically greater than L₀. After removal of one of the BCP blocks, the resulting BCP layer can serve as mask for patterning other layers.

In a second embodiment a conventional lithography process is used to generate a topographic pattern whose guiding features are only slightly higher than the interspatial trenches. In the first DSA step, an ultrathin film of a BCP blend with functional homopolymers is used. Since the height of the topographic features is comparable to the BCP film thickness, a typical graphoepitaxy DSA still occurs. Similarly, a 1:1 chemical pattern forms in the trenches. The ultrathin BCP film is then stripped. This new pattern will be acceptable for a second DSA of a BCP layer with a thickness of typically greater than L₀. Since the second BCP film thickness is much larger than the height of the initial topographic features, the second BCP film also covers the topographic features and thus this new pattern works like a chemical pattern. Thus, DSA over the whole patterned area can be achieved. After removal of one of the BCP blocks, the resulting BCP layer can serve as mask for patterning other layers.

By using this method, it is possible to achieve DSA on the entire patterned area with a large density multiplication factor without the requirement of tight control on the critical dimensions of the guiding features. A large density multiplication factor can be obtained by carrying out the first DSA on conventional topographic prepatterns, or on shallow topographic prepatterns using ultrathin BCP films. The nearly perfect pattern will be “printed” on the initial pattern by the inks The new pattern can serve as a chemical pattern by either removing the topographic features or by using a much thicker BCP film that covers the topographic features. Therefore, the method can reduce the requirements for the conventional lithography processes in terms of throughput, pattern pitch, pattern critical dimensions, and pattern roughness.

For a fuller understanding of the nature and advantages of the present invention, reference should be made to the following detailed description taken together with the accompanying figures.

### BRIEF DESCRIPTION OF THE DRAWING

FIGS. 1A-1E are views illustrating the prior art method for making an imprint template using directed self-assembly (DSA) of block copolymers (BCPs) with a topographic pattern.

FIGS. 2A-2G are illustrations of a first embodiment of the invention, wherein FIGS. 2A, 2B, 2D, 2F, 2G, and 2H are side sectional views of the structure at various stages of the process, FIG. 2C is an expanded sectional view of a portion of FIG. 2B, and FIG. 2E is an expanded sectional view of a portion of FIG. 2D.

FIGS. 3A-3K are illustrations of a second embodiment of the invention, wherein FIGS. 3A, 3B, 3C, 3D, 3E, 3G, 3I, 3J and 3K are side sectional views of the structure at various stages of the process, FIG. 3F is an expanded sectional view of a portion of FIG. 3E, and FIG. 3H is an expanded sectional view of a portion of FIG. 3G.

FIG. 4A is a scanning electron microgram (SEM) image of a top view of the oxygen plasma etched e-beam resist pattern and thus corresponds to a top view of FIG. 3C.

FIG. 4B is top-down SEM image of the BCP layer in FIG. 3G guided by the prepattern and shows the alternating lines of polystyrene (PS) and polymethyl methacrylate (PMMA).

FIG. 4C is a SEM image of a top view of the additional BCP layer in FIG. 3K with alternating parallel PS lines and PMMA lines, except that the PMMA lines 385 have selective removed by oxygen plasma etching.

FIG. 4D is a SEM image of chromium (Cr) lines formed by first removing the PMMA lines from the structure of FIG. 3K, then deposition of a Cr layer over the PS lines and the substrate regions previously covered by the PMMA lines, followed by dry lift-off of the PS lines and the Cr lines on top of the PS lines.

### DETAILED DESCRIPTION OF THE INVENTION

Self-assembling block copolymers (BCPs) have been proposed for creating periodic nanometer (nm) scale features. Self-assembling BCPs typically contain two or more different polymeric block components, for example components A and B, that are immiscible with one another. Under suitable conditions, the two or more immiscible polymeric block components separate into two or more different phases or microdomains on a nanometer scale and thereby form ordered patterns of isolated nano-sized structural units. There are many types of BCPs that can be used for forming the self-assembled periodic patterns. If one of the components A or B is selectively removable without having to remove the other, then an orderly arranged structural units of the un-removed component can be formed.

Specific examples of suitable BCPs that can be used for forming the self-assembled periodic patterns include, but are not limited to: poly(styrene-block-methyl methacrylate) (PS-b-PMMA), poly(ethylene oxide-block-isoprene) (PEO-b-PI), poly(ethylene oxide-block-butadiene) (PEO-b-PBD), poly(ethylene oxide-block-styrene) (PEO-b-PS), poly(ethylene oxide-block-methylmethacrylate) (PEO-b-PMMA), poly(ethyleneoxide-block-ethylethylene) (PEO-b-PEE), poly(styrene-block-vinylpyridine) (PS-b-PVP), poly(styrene-block-isoprene) (PS-b-PI), poly(styrene-block-butadiene) (PS-b-PBD), poly(styrene-block-ferrocenyldimethylsilane) (PS-b-PFS), poly(butadiene-block-vinylpyridine) (PBD-b-PVP), poly(isoprene-block-methyl methacrylate) (PI-b-PMMA), poly(styrene-block-lactic acid) (PS-b-PLA) and poly(styrene-block-dymethylsiloxane) (PS-b-PDMS).

The specific self-assembled periodic patterns formed by the BCP are determined by the molecular volume ratio between the first and second polymeric block components A and B. When the ratio of the molecular volume of the second polymeric block component B over the molecular volume of the first polymeric block component A is less than about 80:20 but greater than about 60:40, the BCP will form an ordered array of cylinders composed of the first polymeric block component A in a matrix composed of the second polymeric block component B. When the ratio of the molecular volume of the first polymeric block component A over the molecular volume of the second polymeric block component B is less than about 60:40 but is greater than about 40:60, the BCP will form alternating lamellae composed of the first and second polymeric block components A and B. When the ratio of B over A is greater than about 80:20 the BCP will form an ordered array of spheres in a matrix of the second component. For lamellar or cylinder forming BCPs, the orientation of the lamellae or the cylinders with respect to the substrate depends on the interfacial energies (wetting properties) of the block copolymer components at both the substrate interface and at the top interface. When one of the block components preferentially wets the substrate (or the top free interface) the block copolymers form layers parallel to the substrate. When the wetting properties at the interface are neutral to either block, then both block components can be in contact with the interface, facilitating the formation of block copolymer domains with perpendicular orientation. In practice, the wetting properties of the substrate are engineered by coating the substrate with “surface modification layers” that tune the wetting properties at the interface. Surface modification layers are usually made of polymer brushes or mats typically (but not necessarily) composed of a mixture of the constituent block materials of the BCP to be used.

The periodicity or natural pitch (L₀) of the repeating structural units in the periodic pattern BCP components is determined by intrinsic polymeric properties such as the degree of polymerization N and the Flory-Huggins interaction parameter χ. L₀ scales with the degree of polymerization N, which in turn correlates with the molecular weight M. Therefore, by adjusting the total molecular weight of the BCP, the natural pitch (L₀) of the repeating structural units can be selected.

To form the self-assembled periodic patterns, the BCP is first dissolved in a suitable solvent system to form a BCP solution, which is then applied onto a surface to form a thin BCP layer, followed by annealing of the thin BCP layer, which causes phase separation between the different polymeric block components contained in the BCP. The solvent system used for dissolving the BCP and forming the BCP solution may comprise any suitable non-polar solvent, including, but not limited to: toluene, propylene glycol monomethyl ether acetate (PGMEA), propylene glycol monomethyl ether (PGME), and acetone. The BCP solution can be applied to the substrate surface by any suitable techniques, including, but not limited to: spin casting, coating, spraying, ink coating, dip coating, etc. Preferably, the BCP solution is spin cast onto the substrate surface to form a thin BCP layer. After application of the thin BCP layer onto the substrate surface, the entire substrate is annealed to effectuate microphase segregation of the different block components contained by the BCP, thereby forming the periodic patterns with repeating structural units.

The BCP films in the above-described techniques self-assemble without any direction or guidance. This undirected self-assembly results in patterns with defects so it is not practical for applications that require long-range ordering. However, directed self-assembly (DSA) of block copolymers (BCPs) has been proposed for making generally parallel lines that can be used as an etch mask. The etch mask can be used in the manufacturing of integrated circuits to pattern intermediate layers formed on a semiconductor wafer substrate. For example, DSA of BCP has been proposed for making FinFET devices. A FinFET is composed of an array of discrete single crystal Si mesas or “fins” having widths on the order of 10 nm and heights in the 20-40 nm range. This is described in Tsai, et al., “Two-Dimensional Pattern Formation Using Graphoepitaxy of PS -b-PMMA Block Copolymers for Advanced FinFET Device and Circuit Fabrication”, ACS Nano, Vol. 8, No. 5, 5227-5232 2014. The etch mask can also be used to make imprint templates, which can be used in making integrated circuits and patterned-media magnetic recording disks. For example, U.S. Pat. No. 7,976,715 and U.S. Pat. No. 8,119,017, both assigned to the same assignee as this application, describe DSA of BCPs for making imprint templates with radial lines and concentric circular lines that are use to make patterned-media magnetic recording disks. Pending application Ser. No. 14/067,769, filed Oct. 13, 2013 and assigned to the same assignee as this application, describes first depositing a blend of a BCP and functional homopolymers, referred to as inks, on the patterned sublayer and annealing. The inks selectively distribute into blocks by DSA, and part of the inks graft on the substrate underneath the blocks. The BCP blend layer is then rinsed away, leaving the grafted inks A second layer of BCP is then deposited and annealed as a second DSA step to form alternating lines of the BCP components.

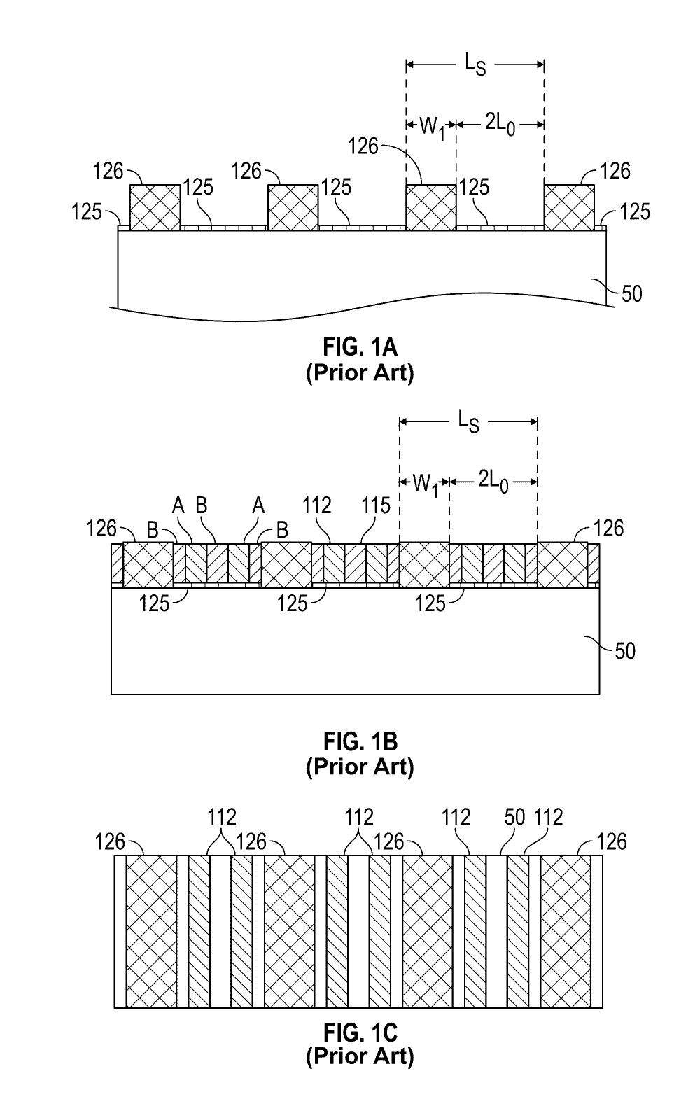

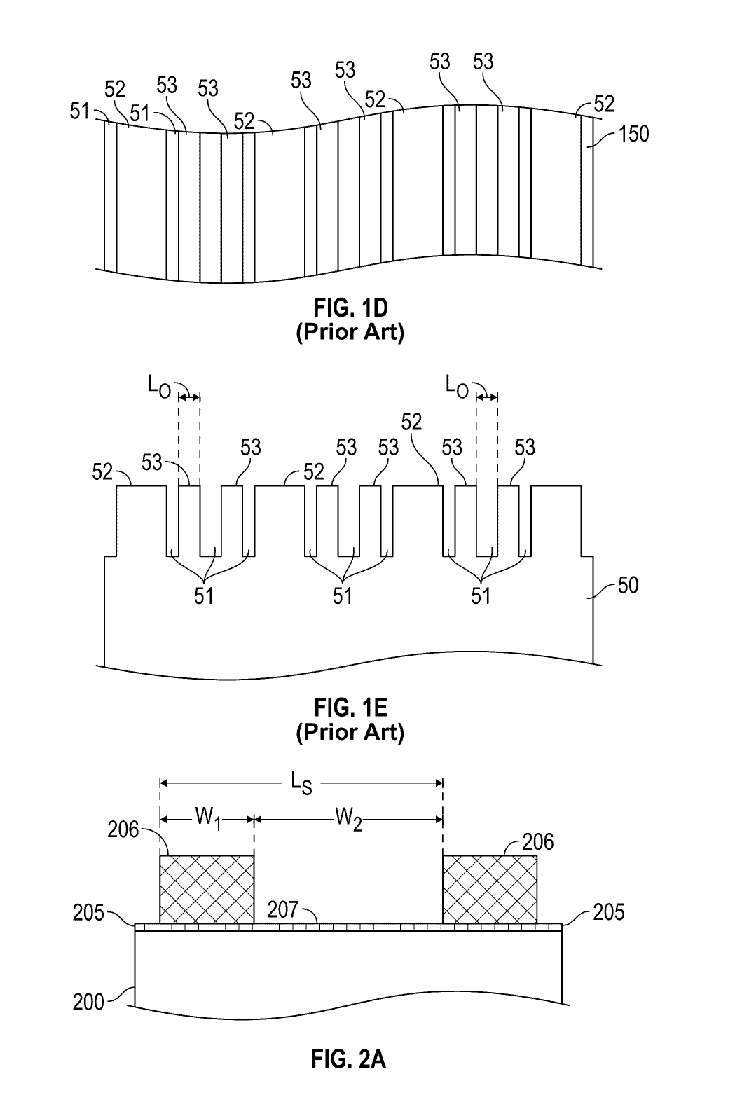

DSA of BCPs has also been proposed using a topographic pattern instead of a chemical contrast pattern as the patterned sublayer. The prior art method for making an imprint template using a topographic pattern will be described in general terms with FIGS. 1A-1E for an example where the substrate will become an imprint template with protrusions in a pattern of parallel bars. FIG. 1A is a side sectional view showing the substrate 50 with a patterned sublayer of generally parallel topographic stripes 126 and intermediate regions 125. The stripes 126 are photoresist or e-beam resist stripes after patterning and development, or are formed of a material like silicon, silicon nitride, silicon oxide, gold or carbon that is transferred from a resist pattern. The regions 125 may be a neutral random copolymer PS-r-PMMA brush or mat grafted on the substrate 50. The stripes have a width W₁ and a pitch Ls of approximately (W₁+nL₀) (n=2 in this example). In FIG. 1B, a BCP has been deposited into the regions 125 and annealed. This results in self assembly of alternating A component, e.g., PS, parallel lines 112 and B component, e.g., PMMA, parallel lines 115 between the resist stripes 126. The topographic pattern directs the self-assembly of the BCP A and B components with a natural pitch of L₀. In the top view of FIG. 1C, the portions of parallel lines 115, the B component (PMMA), are then selectively removed by a wet etch or a dry etch process. This leaves generally parallel lines 112 of the A component (PS) in addition to the resist stripes 126 on the template 50. The problem with this prior art method is that the resist stripes 126 remain. They can either be left on the substrate during etching or trimmed prior to etching, for example trimmed to have the same width as the lines 112. In FIG. 1D, the resist stripes 126 and A component lines 112 are used as a mask during a dry etch process. The resist stripes 126 and the material of parallel lines 112 are then removed, leaving recesses 51, bars 52 where the resist stripes 126 were located, and bars 53 where the lines 112 of the A component were located. This structure as shown in the side sectional view of FIG. 1E, with a pattern of protrusions formed as parallel bars 53. The spaced bars 53 may be parallel generally straight lines with a width of L₀ and a spacing of L₀, as shown in FIG. 1E, for example for making an imprint template for use in making MPU, DRAM and NAND flash devices. The spaced bars 53 may also be concentric rings or radial lines for making an imprint template for use in making patterned-media magnetic recording disks. If the bars are radial lines they may have spacing as small as 0.9L₀ at the radially inner point and as large as 1.1L₀ at the radially outer point. As is apparent from FIG. 1E, this prior art method prevents the entire surface of the substrate from being used because of the presence of the bars 52, so that the number of parallel bars 53 that can be formed between bars 52 is limited, typically no more than 20.

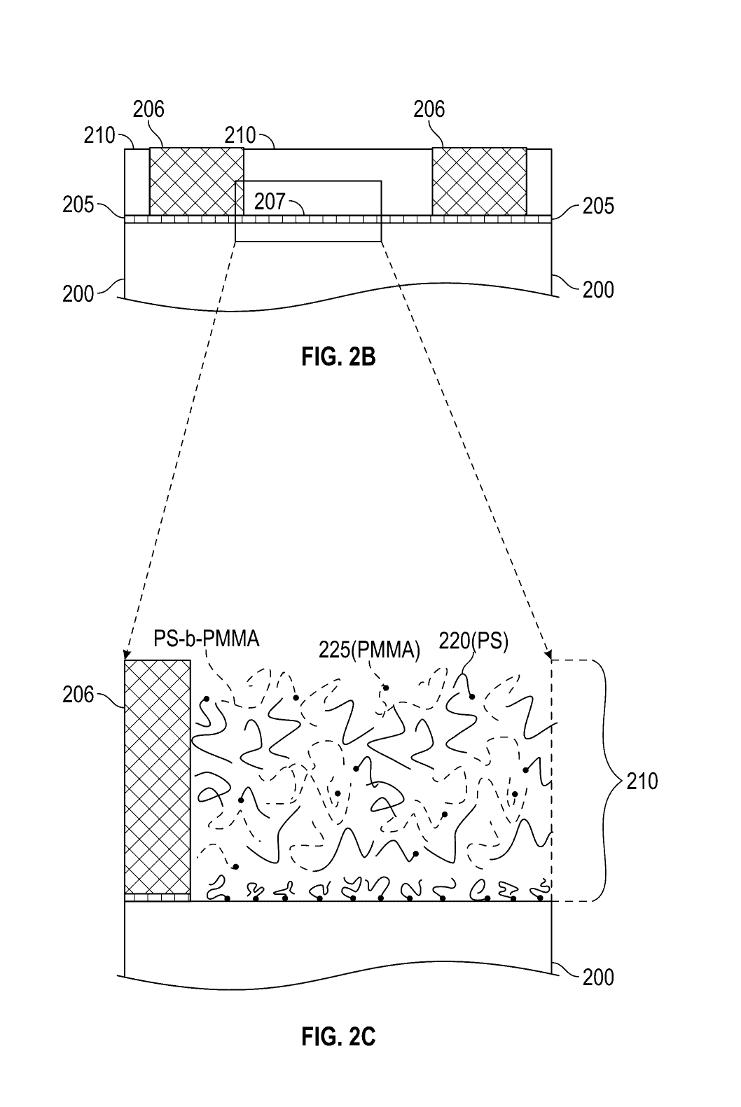

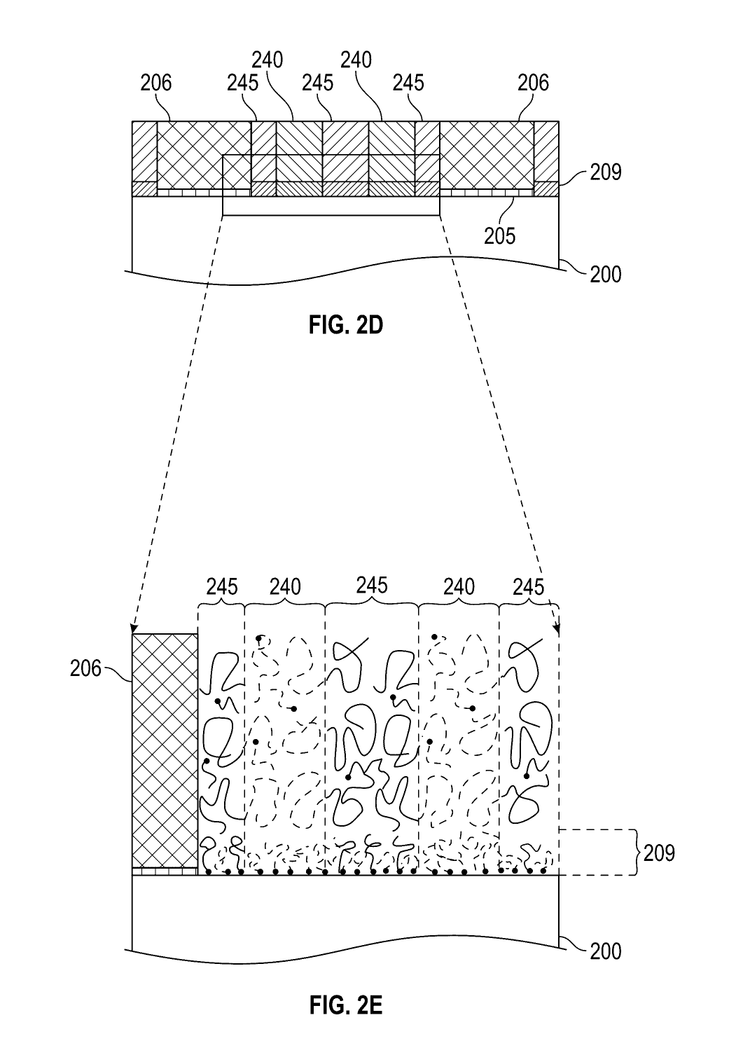

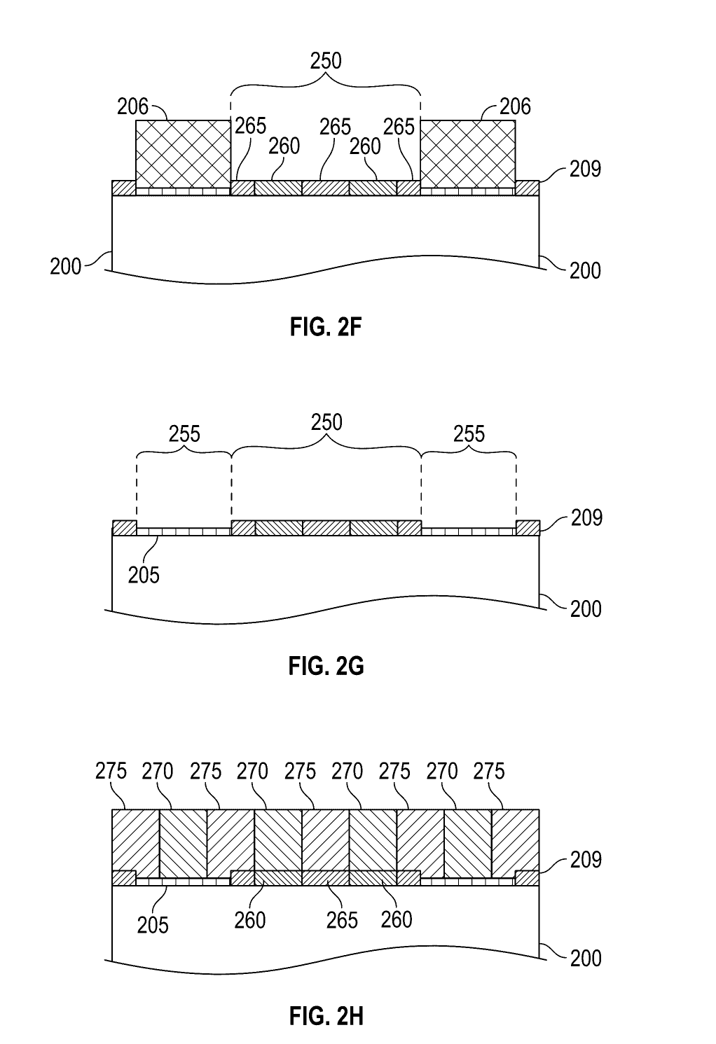

Embodiments of the method of this invention use intermediate steps between formation of the topographic pattern and deposition of the BCP and thus replace the prior art method illustrated and described above with respect to FIGS. 1A-1E. A first embodiment of the invention is illustrated in FIGS. 2A-2H for an example where the BCP is poly(styrene-block-methyl methacrylate) (PS-b-PMMA) with L₀=27 nm.

FIG. 2A is a perspective view of a substrate 200 with a patterned sublayer 205 that acts as a topographic pattern. The substrate 200 may be formed of any suitable material, such as, but not limited to, silicon-on-insulator (SOI), single-crystal Si, amorphous Si, silica, fused quartz, silicon nitride, carbon, tantalum, molybdenum, chromium, alumina and sapphire. The substrate may also be an intermediate layer formed on a semiconductor wafer or SOI base, such as an amorphous carbon layer or a silicon nitride (SiN) layer. The previously-cited Tsai et al. article describes the use of DSA to form a BCP pattern on a SiN layer above a SOI base for making an etch mask to pattern fins in FinFET devices.

In FIG. 2A a first layer 205 is deposited on the substrate 200, followed by deposition and patterning of a photoresist layer or e-beam resist layer into stripes 206. In case of the DSA of perpendicularly oriented lamellae, this results in a patterned topographic sublayer which is typically a periodic pattern of generally parallel stripes 206 alternated by stripes 207. The width of each stripe 206 (W₁) and each stripe 207 (W₂) are W₁ approximately equal to nL₀ and W₂ approximately equal to mL₀, respectively, and the pitch of the stripes 206 is Lₛ approximately equal to (n+m)L₀, where n and m are integers greater than or equal to 1. Because it may not be possible to precisely match the width and spacing of the resist stripes during the lithographic process that forms the patterned sublayer of stripes 206 and 207, the phrase “approximately” as used herein in reference to the stripe widths, spacing and pitch shall mean the referenced term plus or minus 10%. The sidewalls of the stripes 206 are formed of a material that is preferentially wetted by one of the blocks of the BCP. The chemistry of the alternate stripes 207 is generally neutral to the blocks. Because the stripes 206 are taller than the stripes 207, the pattern is referred to as a topographic pattern. In the prior art, there are various types of topographic patterns specifically for PS-b-PMMA, which means different pairing of 206 and 207 stripes. For example, the 206 stripes can be a cross-linked PMMA mat, cross-linked polystyrene (XPS), e-beam resist HSQ (hydrogen silsesquioxane), photoresist, anti-reflection coating, or a material like silicon, silicon nitride, silicon oxide, gold or carbon. The layer 205 and thus the stripes 207 can be a neutral brush or neutral mat, like a neutral functionalized random copolymer PS-r-PMMA brush or a neutral cross-linked random copolymer PS-r-poly(methyl methacrylate)(PMMA) mat, that binds to the substrate 200.

A mat layer is a cross-linked polymer layer. The cross-linkable polymer may be spin-coated on the substrate to a thickness of 4-15 nm. The as-spun film is then annealed or treated by UV light for the cross-linking units to carry out the cross-linking After cross-linking, the cross-linked polymer layer is typically referred as a mat layer. The film thickness is similar to that of the as-spun layer. A brush layer is a monolayer of a functional polymer grafted on the substrate. The functional polymer may be applied on the substrate to a thickness greater than 5 nm. The as-spun film is annealed for the functional groups to graft to the substrate surface. After annealing, any ungrafted brush material is rinsed away in a suitable solvent (e.g., toluene, PGMA, or NMP). The thickness of the brush layer is typically 1-15 nm, which is determined by the properties of the functional polymer such as chemistry, molecular weight, location of the functional group, etc. One of the main differences between these two is that a mat layer is denser than a brush layer and can prevent a further brush grafting on the underlying substrate surface.

For DSA, additional steps are required to create a topographic pattern. These steps may include e-beam lithography, photolithography or nanoimprint lithography and potentially other processing procedures. Referring again to FIG. 2A, in the present example, a layer 205 of random copolymer PS-r-PMMA-OH brush with a thickness of 3-8 nm is first deposited on a silicon substrate 200, which results in the brush molecules binding to the substrate 200. This is followed by deposition of an e-beam resist layer or photoresist layer on top to a thickness between about 15 to 200 nm. After the resist is exposed and developed by e-beam lithography or photolithography, a topographic pattern of resist stripes 206 and underlying stripes 207 is formed with a stripe pitch Lₛ of approximately (n+m)L₀. The e-beam resist, for example hydrogen silsesquioxane (HSQ), may serve as the topographic features or stripes 206. The topographic features 206 may also be formed by transferring the e-beam resist pattern to another material. The width of the stripes 206 and 207 can be tuned by e-beam doses and/or additional wet etching.

Next, in FIG. 2B and the expanded sectional view of FIG. 2C a solution of a BCP blended with homopolymers with functional groups is deposited, for example by spin-coating, as a thin film 210 onto the stripes 207 of the topographic pattern. Preferably the homopolymers with functional groups are the same as the polymers in the BCP and the functional groups are functional end groups. The preferred BCPs are PS-b-PMMA and polystyrene block poly 2-vinylpyridine (PS-b-P2VP). The preferred functional groups for the homopolymers are hydroxyl (OH) and amine (NH₂). This layer is deposited to a thickness that is comparable to the height of stripes 206. The functionalized homopolymers are sometimes called “inks” because they are added to the blend.

In the example of FIGS. 2A-2H, the BCP is PS-b-PMMA and the homopolymers are OH-terminated PS (item 220) and OH-terminated PMMA (item 225). The blend may be made up of 70-99% PS-b-PMMA and 30-1% inks The ratio between PS-OH and PMMA-OH is typically chosen as the same as the ratio of PS block and PMMA block in the BCP. Preferably the length of the ink molecules is chosen to be longer than the length of the brush molecules in stripes 207 already bound to the substrate 200.

Next in FIG. 2D and the expanded sectional view of FIG. 2E the film 210 is annealed, for example by solvent annealing or by heating to 250° C. for at least 10 minutes. This results in a micro-phase separation (e.g., self-assembly into nanoscale domains) and allows the inks to be sequestered or phase separated into respective blocks of PS 240 and PMMA 245 within the BCP. Because the sidewalls of the HSQ are polar, the more polar PMMA is attracted to the sidewalls of stripes 206. If the stripes 206 were formed of a cross-linked PMMA mat, the sidewalls would attract the PMMA. This causes the PMMA 245 and PS 240 to self-assemble between the sidewalls of adjacent stripes 206, as shown in FIG. 2E. Meanwhile, a fraction of the ink molecules will also react with the substrate 200 in the regions 207. This results in a layer 209 of predominantly grafted inks, but also grafted brush, in this example the grafted PS-r-PMMA-OH, having a pattern with the same geometry and feature size as the BCP pattern of PS 240 and PMMA 245. Since the DSA is guided by a topographic pattern, defect-free patterns can be achieved with a density multiplication factor greater than 4. However, perfect DSA cannot be obtained on top of the topographic stripes 206.

After the film 210 has been annealed, it is rinsed in a suitable solvent, for example toluene or NMP, to remove the BCP and any functionalized polymers (inks) that are not bound to the substrate in the regions 209. This leaves the structure depicted in FIG. 2F with a patterned sublayer of stripes 206 and intermediate regions 250 that contain the self-assembled pattern of bound PS-OH (260) and PMMA-OH (265). After rinsing, region 250 will change to 1:1 chemical pattern. Stripes 206 can then be removed by be rinsing in a suitable solvent, for example in an aqueous solution of sodium hydroxide if stripes 206 are HSQ. The resulting pattern will have the 1:1 chemical pattern in regions 250 and neutral brush in regions 255 (FIG. 2G).

In FIG. 2H an additional layer of BCP is deposited, for example by spin-coating, and the additional layer of BCP is annealed by solvent annealing or by heating to about 250° C. for at least 2 minutes. The underlying pattern of neutral brush in regions 255 and 1:1 chemical pattern regions 250 directs the BCP components to self-assemble into PS lines 270 and PMMA lines 275, with the PS lines 270 forming on the PS-OH 260 and the PMMA lines 275 forming on the PMMA-OH 265. The PS lines 270 and PMMA lines 275 self-assemble as lamellae perpendicular to the substrate.

If the BCP used in the solution deposited on the patterned sublayer in the step of FIGS. 2B and 2C was blended with the homopolymers of the BCP, e.g., if the BCP contains copolymers A and B and the homopolymers with functional groups are A and B, then this additional layer 270 of BCP is the same BCP. Thus in the example of FIG. 2H, the additional layer 270 of BCP is PS-b-PMMA. However, if the BCP used in the solution deposited on the patterned sublayer in the step of FIG. 2B and 2C was blended with different homopolymers than are in the BCP, e.g., if the BCP contains copolymers A and B and the homopolymers with functional groups are polymers C and D, then this additional layer 270 is a BCP with polymers C and D.

After the structure shown in FIG. 2H is formed according to embodiments of the method of this invention, one of the BCP components can be removed, leaving the other component as an etch mask for transferring the pattern into substrate 200. These subsequent steps are known in the prior art, for example as shown and described above in FIGS. 1C-1E.

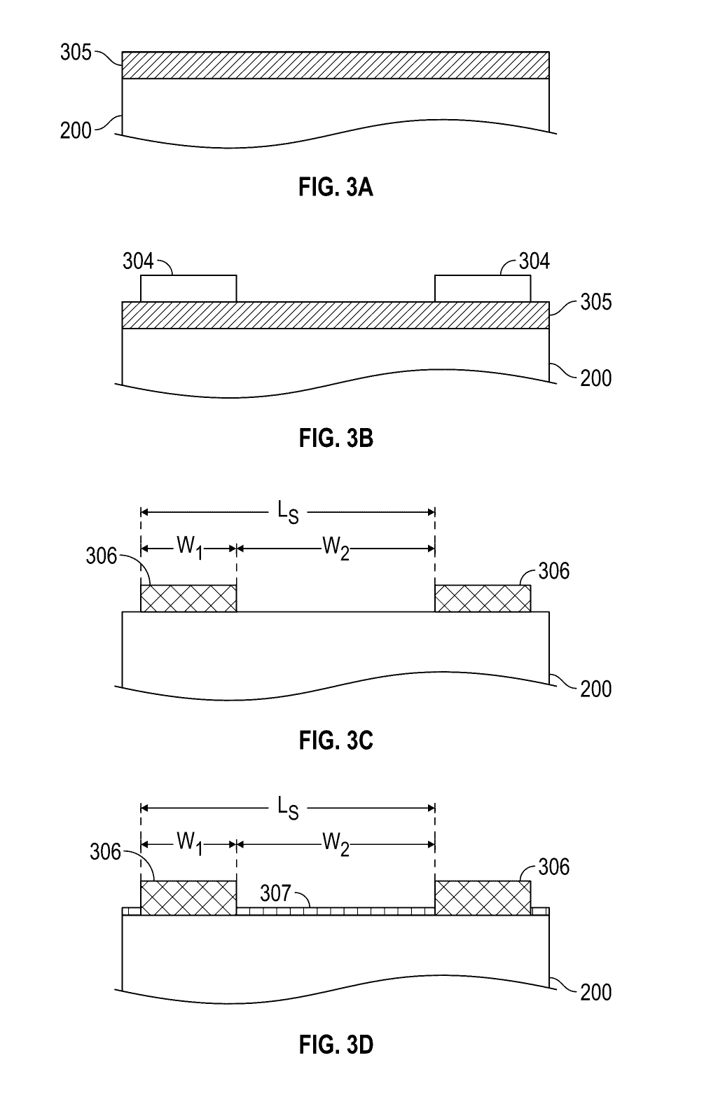

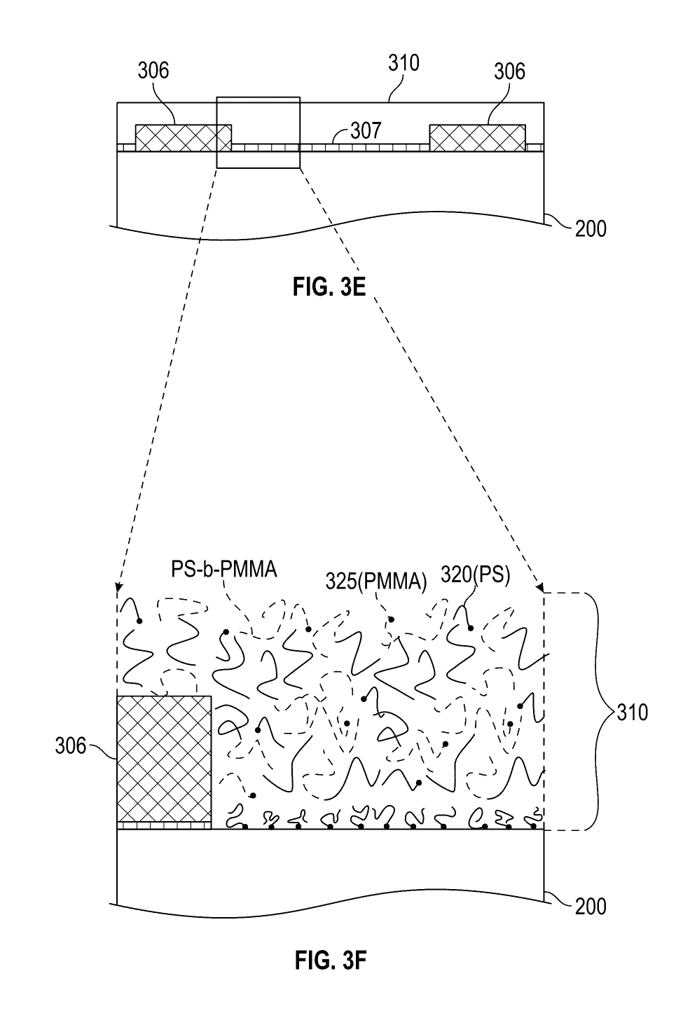

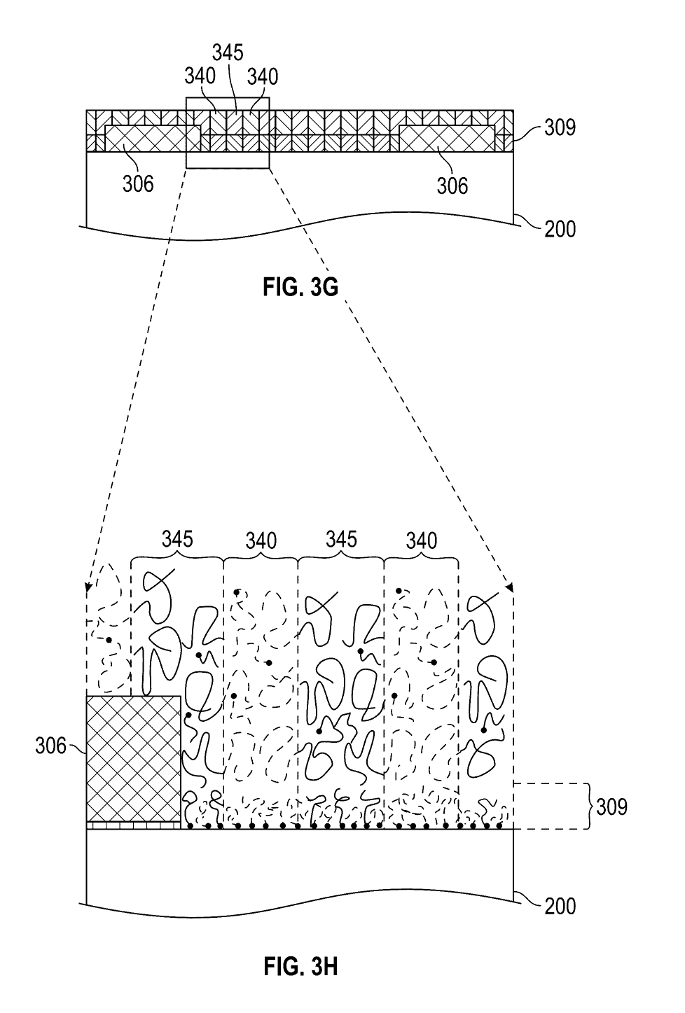

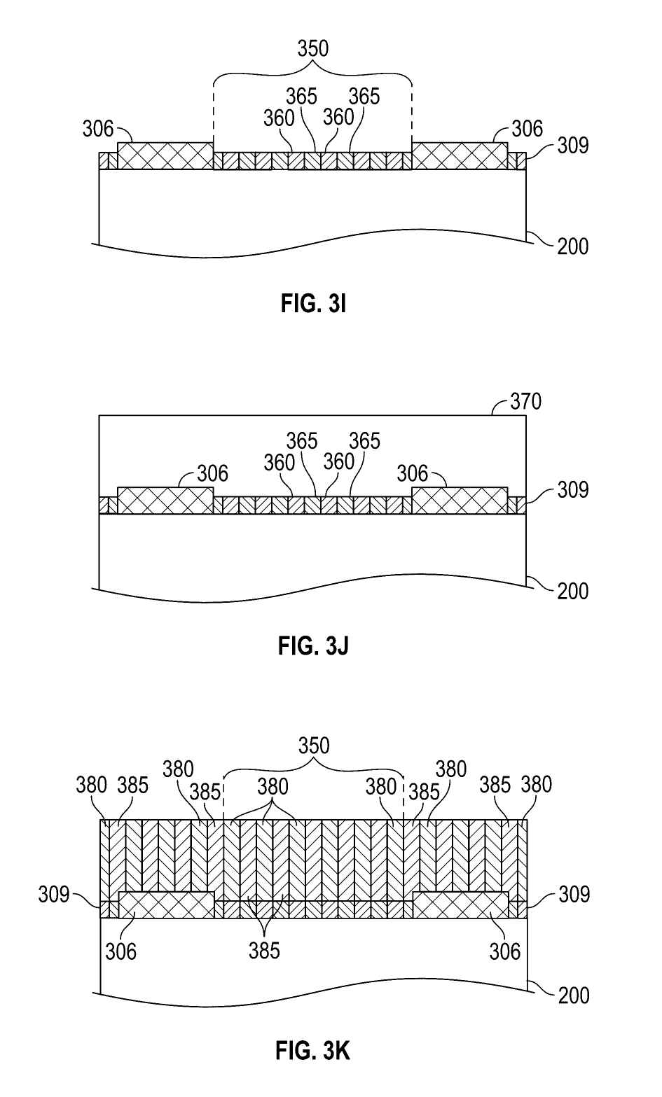

A second embodiment of the invention is illustrated in FIGS. 3A-3H for an example where the BCP is poly(styrene-block-methyl methacrylate) (PS-b-PMMA) with L₀=27 nm. Referring to FIG. 3A, a layer 305 of material with a thickness of 5-15 nm is formed on substrate 200. The material for layer 305 may be any of the materials used for stripes 206, but is preferably a neutral PS-r-PMMA mat. Then, in FIG. 3B an e-beam resist or photoresist layer is deposited on the layer 305 and e-beam lithography or photolithography is utilized to generate grating patterns of resist stripes 304 with a stripe pitch Lₛ=(m+n)L₀. The resist pattern is then exposed to oxygen plasma etching so that the exposed portions of layer 305 are etched away, leaving stripes 306. This also oxidizes the sidewalls of the stripes 306. The remaining resist pattern is rinsed away in a suitable solvent (e.g., toluene, PGMA, or NMP), leaving the structure as shown in FIG. 3C with stripes 306 with a stripe pitch Lₛ=(m+n)L₀. The width of the resulting stripes 306 may also be tuned to be W₁=mL₀ by lateral etching.

Next, in FIG. 3D a functionalized random copolymer “PS-r-PMMA” with a hydroxyl (OH) group (e.g., PS-r-PMMA-OH) consisting of ˜50% styrene is spin-coated on the substrate 200 and annealed. Since stripes 306 are dense, PS-r-PMMA-OH can only graft to the substrate 200 in the intermediate regions between stripes 306. After rinsing away the ungrafted brush material in toluene or NMP, the remaining brush forms stripes 307 of grafted PS-r-PMMA-OH with width of nL₀. FIG. 3D shows the topographic pattern of stripes 306 and stripes 307. The stripes 306 are taller than stripes 307 by about 3-10 nm.

Next, in FIG. 3E and the expanded sectional view of FIG. 3F a solution of a BCP blended with homopolymers with functional groups is deposited, for example by spin-coating, as a thin film 310 onto the stripes 307 of the topographic pattern. Preferably the homopolymers with functional groups are the same as the polymers in the BCP and the functional groups are functional end groups. The preferred BCPs are PS-b-PMMA and polystyrene block poly 2-vinylpyridine (PS-b-P2VP). The preferred functional groups for the homopolymers are hydroxyl (OH) and amine (NH₂). This layer is deposited to a thickness in the range of 10 to 20 nm, which is comparable to the height of stripes 306. The functionalized homopolymers are sometimes called “inks” because they are added to the blend.

In the example of FIGS. 3A-3K, the BCP is PS-b-PMMA and the homopolymers are OH-terminated PS (item 320) and OH-terminated PMMA (item 325). The blend may be made up of 70-99% PS-b-PMMA and 30-1% inks The ratio between PS-OH and PMMA-OH is typically chosen as the same as the ratio of PS block and PMMA block in the BCP.

Next in FIG. 3G and the expanded sectional view of FIG. 3H the film 310 is annealed, for example by solvent annealing or by heating to 250° C. for at least 10 minutes. This results in a micro-phase separation (e.g., self-assembly into nanoscale domains) and allows the inks to be sequestered or phase separated into respective blocks of PS 340 and PMMA 345 within the BCP. The PMMA is attracted to the oxidized sidewalls of stripes 306. Stripes 306 are preferably a neutral PS-r-PMMA mat, but whose sidewalls have been oxidized and become PMMA-wetting. This causes the PMMA 345 and PS 340 to self-assemble between the sidewalls of adjacent stripes 306, as shown in FIG. 3H. Meanwhile, a fraction of the ink molecules will also react with the substrate 200 in the regions 307. This results in a layer 309 of predominantly grafted inks, but also grafted brush, in this example the grafted PS-r-PMMA-OH, having a pattern with a pattern with the same geometry and feature size as the BCP pattern of PS 340 and PMMA 345. The thickness of BCP film 310 is comparable to the height of stripes 306, and the pattern of stripes 306 and stripes 307 works like a topographic pattern to cause the PS 340 and PMMA 345 to self-assemble between the sidewalls of adjacent stripes. The PS 340 and PMMA 345 also assemble on the tops of the neutral mat stripes 306.

After the film 310 has been annealed, it is rinsed in a suitable solvent, for example in a solution of toluene or NMP, to remove the BCP and any functionalized polymers (inks) that are not bound to the substrate in regions 309. This leaves the structure depicted in FIG. 3I with a patterned sublayer of stripes 306 and intermediate regions 350 that contain the self-assembled pattern of bound PS-OH and PMMA-OH shown in the sectional view of FIG. 3H. After rinsing, region 350 will change to 1:1 chemical pattern.

In FIG. 3J an additional layer 370 of BCP with a thickness greater than that of layer 310 is deposited, for example by spin-coating, over the patterned sublayer of stripes 306 and regions 350. In FIG. 3K the additional layer 370 of BCP is annealed by solvent annealing or by heating to about 250° C. for at least 2 minutes. This additional BCP layer 370 has a thickness preferably in the range of 25 to 200 nm. The underlying pattern of stripes 306 and regions 350 directs the BCP components to self-assemble into PS lines 380 and PMMA lines 385, with the PS lines 380 forming on the PS-OH 360 and the PMMA lines 385 forming on the PMMA-OH 365. The PS lines 380 and PMMA lines 385 self-assemble as lamellae perpendicular to the substrate.

After the structure shown in FIG. 3K is formed according to embodiments of the method of this invention, one of the BCP components can be removed, leaving the other component as an etch mask for transferring the pattern into substrate 200. These subsequent steps are known in the prior art, for example as shown and described above in FIGS. 1C-1E.

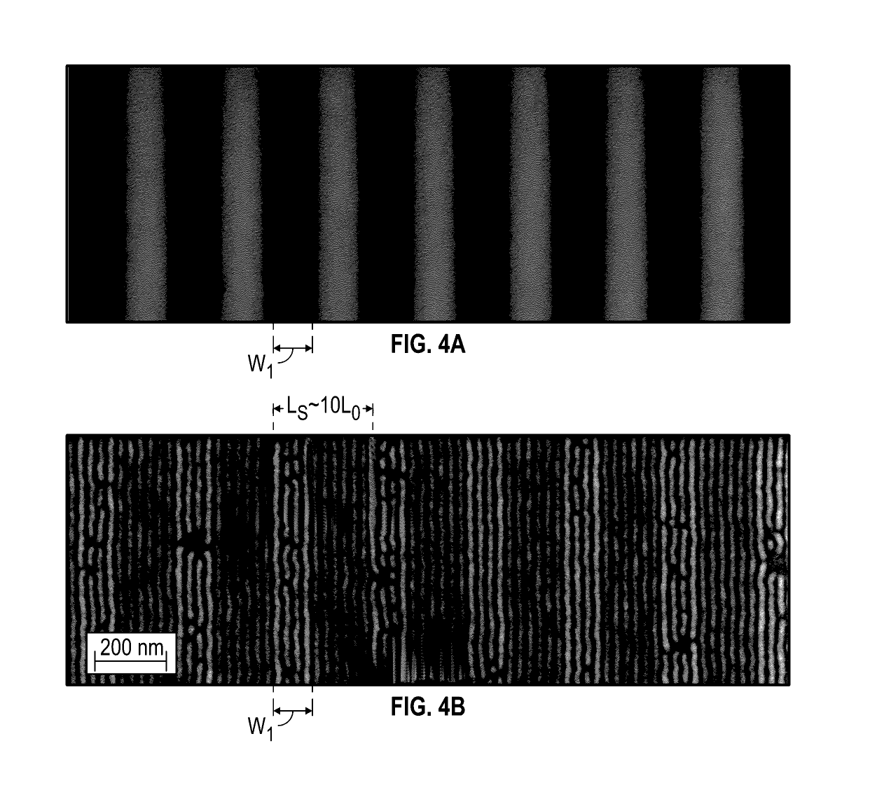

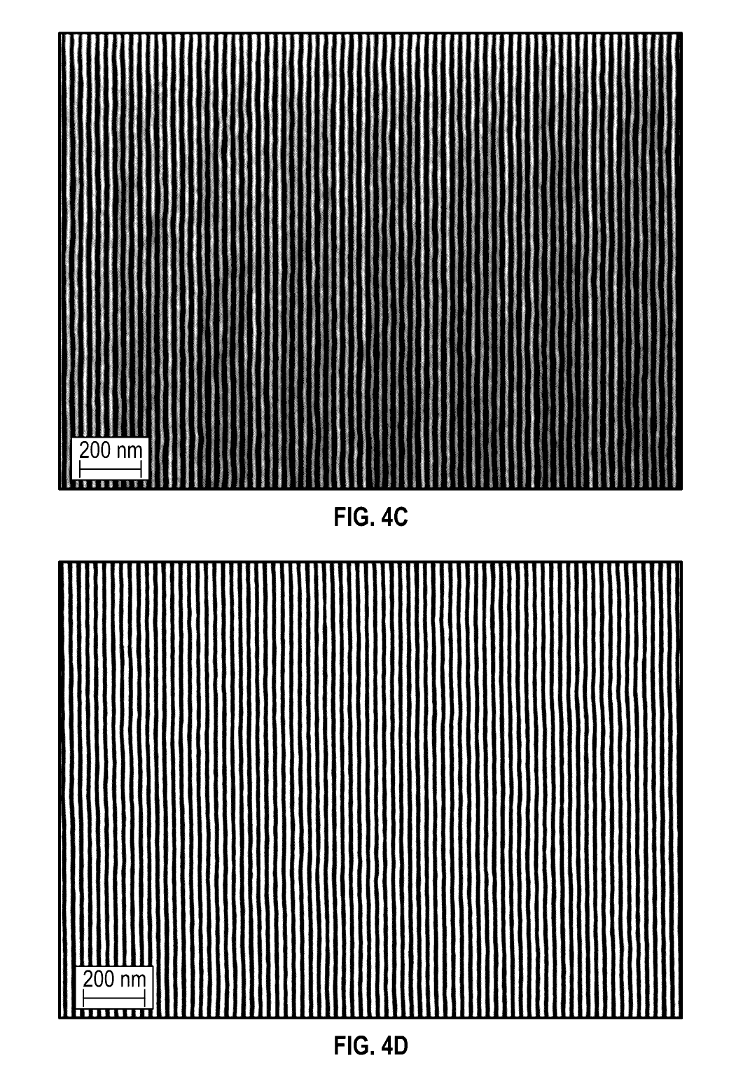

DSA with a high-density multiplication factor on a patterned area of XPS stripes 306 and stripes 307 was demonstrated according to embodiments of the method of this invention. A pattern with a density multiplication factor of 10 was generated. The pattern had XPS guiding stripes 306 with width W₁ of ˜108 nm (4L₀), neutral PS-r-PMMA-OH brush as stripes 307 with width W₂ of ˜162 nm (6L₀), and Lₛ˜270 nm (10L₀). FIG. 4A is a SEM image of a top view of the oxygen plasma etched e-beam resist pattern and thus corresponds to a top view of FIG. 3C. FIG. 4B is top-down SEM image of the BCP layer 310 in FIG. 3G guided by the pattern. FIG. 4B shows that the PS lines 340 and PMMA lines 345 are substantially parallel and uniform on top of stripes 307. FIG. 4C is a SEM image of a top view of the additional BCP layer 370 in FIG. 3K with alternating parallel PS lines 380 and

PMMA lines 385, except that the PMMA lines 385 have selective removed by oxygen plasma etching. FIG. 4D is a SEM image of chromium (Cr) lines formed by first removing the PMMA lines from the structure of FIG. 3K, then deposition of a Cr layer over the PS lines and the substrate regions previously covered by the PMMA lines, followed by dry lift-off of the PS lines and the Cr lines on top of the PS lines.

While the present invention has been particularly shown and described with reference to the preferred embodiments, it will be understood by those skilled in the art that various changes in form and detail may be made without departing from the spirit and scope of the invention. Accordingly, the disclosed invention is to be considered merely as illustrative and limited in scope only as specified in the appended claims.

1. A method of directed self-assembly (DSA) of a block copolymer (BCP) having a natural pitch L₀ comprising:
providing a substrate;
forming on the substrate a topographic pattern of first and second alternating generally parallel stripes, the first stripes having a height higher than the second stripes and having sidewalls that preferentially wet one of the BCP blocks, the first stripes having a stripe width of approximately nL₀ and the second stripes having a stripe width of approximately mL₀, where n and m are integers greater than or equal to 1, the first stripes having a stripe pitch Lₛ of approximately (n+m)L₀;
depositing on the second stripes and the sidewalls of the first stripes a solution comprising a first BCP of polymers A and B without functional groups, a polymer C with a functional group and a polymer D with a functional group;
annealing said deposited solution to cause polymers C and D to self assemble and bind with the second stripes to the substrate;
removing the first BCP and unbound polymers, leaving the self-assembled bound polymers C and D;
removing the first stripes;
depositing on the self-assembled bound polymers C and D a layer of a second BCP of polymers C and D without functional groups; and
annealing said layer of second BCP to cause DSA of the second BCP into alternating lines of polymers C and D, said alternating lines having a line pitch of approximately L₀.

2. The method of claim 1 wherein polymer A is identical to polymer C and polymer B is identical to polymer D, whereby the first BCP is identical to the second BCP.

3. The method of claim 1 wherein the polymers C and D with functional groups are copolymers of a BCP.

4. The method of claim 1 wherein polymer A is polystyrene (PS), polymer B is poly(methyl methacrylate) (PMMA), polymer C is PS and polymer D is poly 2-vinylpyridine (P2VP).

5. The method of claim 1 wherein polymer A is PS, polymer B is P2VP, polymer C is PS and polymer D is PMMA.

6. The method of claim 1 wherein the first stripes are formed of one of a photoresist, an anti-reflection coating, HSQ (hydrogen silsesquioxane) resist, a cross-linked polymer mat, silicon, silicon nitride, silicon oxide, gold and carbon.

7. The method of claim 1 wherein the second stripes are formed of one of a neutral functionalized random copolymer PS-r-PMMA brush and a neutral cross-linked random copolymer PS-r-poly(methyl methacrylate)(PMMA) mat.

8. The method of claim 1 wherein forming the topographic pattern comprises depositing a layer of polymer brush material on the substrate, depositing resist on the polymer brush material, patterning the resist by lithography, and developing the exposed resist, wherein the topographic pattern comprises first stripes of resist and second stripes of polymer brush material between said first stripes.

9. The method of claim 1 wherein forming the topographic pattern comprises depositing a polymer mat on the substrate, depositing a resist on the mat, patterning the resist with lithography, etching the mat and removing the resist leaving said first stripes of mat and exposed substrate between said first stripes, and depositing a random copolymer brush material comprising PS and poly(methyl methacrylate) (PMMA) having an OH end group (PS-r-PMMA-OH) to cause the PS-r-PMMA-OH to bind to the exposed substrate and thereby form said second stripes.

10. The method of claim 1 wherein the first polymer having a functional group is PS-OH and the second polymer having a functional group is PMMA-OH.

11. The method of claim 1 further comprising, after annealing said layer of second BCP to cause DSA of the BCP into alternating lines of polymers C and D, patterning the substrate using the lines of one of polymers C and D as a mask.

12. The method of claim 1 wherein providing a substrate comprises providing a substrate selected from silicon-on-insulator (SOI), single-crystal Si, amorphous Si, silica, fused quartz, silicon nitride, carbon, tantalum, molybdenum, chromium, alumina and sapphire.

13. The method of claim 1 wherein providing a substrate comprises providing an intermediate layer formed on a base selected from a semiconductor wafer and silicon-on-insulator (SOI).

14. The method of claim 1 wherein providing a substrate comprises providing an intermediate layer formed on a semiconductor wafer.

15. The method of claim 1 wherein said alternating lines of first and second polymers form a pattern selected from parallel generally straight lines, generally radial lines, and generally concentric circular lines.

16. A method of forming parallel generally straight lines on a substrate selected from a semiconductor wafer and silicon-on-insulator (SOT) using directed self-assembly (DSA) of a block copolymer (BCP) having a natural pitch L₀ comprising:
forming on the substrate a topographic pattern of first and second alternating generally parallel stripes, the first stripes having a height higher than the second stripes and having sidewalls that preferentially wet one of the BCP blocks, the first stripes having a stripe width of approximately nL₀ and the second stripes having a stripe width of approximately mL₀, where n and m are integers greater than or equal to 1, the first stripes having a stripe pitch Lₛ of approximately (n+m)L₀;
depositing on the second stripes and the sidewalls of the first stripes a solution comprising a first BCP of polymers A and B without functional groups, a polymer C with a functional group and a polymer D with a functional group;
annealing said deposited solution to cause polymers C and D to self assemble and bind with the second stripes to the substrate;
removing the first BCP and unbound polymers, leaving the self-assembled bound polymers C and D;
depositing on the self-assembled bound polymers C and D a layer of a second BCP of polymers C and D without functional groups;
annealing said layer of second BCP to cause DSA of the second BCP into alternating lines of polymers C and D, said alternating lines having a line pitch of approximately L₀; and
patterning said layer of material using the lines of one of polymers C and D as a mask, leaving parallel generally straight lines of said material.

17. The method of claim 16 wherein polymer A is identical to polymer C and polymer B is identical to polymer D, whereby the first BCP is identical to the second BCP.

18. The method of claim 16 wherein the first polymer having a functional group is PS-OH and the second polymer having a functional group is PMMA-OH.

19. The method of claim 16 further comprising depositing an intermediate layer on the substrate prior to forming said patterned sublayer.

20. The method of claim 16 wherein forming the topographic pattern comprises depositing a polymer mat on the substrate, depositing a resist on the mat, patterning the resist with lithography, etching the mat and removing the resist leaving said first stripes of mat and exposed substrate between said first stripes, and depositing a random copolymer brush material comprising PS and poly(methyl methacrylate) (PMMA) having an OH end group (PS-r-PMMA-OH) to cause the PS-r-PMMA-OH to bind to the exposed substrate and thereby form said second stripes.
